(19) United States
(12) Patent Application Publication
(10) Pub. No.: US 2004/0113704 A1
(43) Pub. Date: Jun. 17, 2004

(54) [PHASE LOCK LOOP CIRCUIT AND OPERATION METHOD THEREOF]

(76) Inventor: CHIN-TE HO, KAOHSIUNG COUNTY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,840

(22) Filed: Aug. 21, 2003

(30) Foreign Application Priority Data
Sep. 13, 2002 (TW) 91121059

(51) Int. Cl. H03L 7/00

(52) U.S. Cl. 331/1 A

(57) ABSTRACT

A counter is employed to compare two values and then output a difference value between the two values: one value is produced by the counter during a cycle of input frequency and another is produced by the counter during a cycle of output frequency. The VCO (voltage control oscillation) controls the tuning speed of output frequency depending on the difference value, and so the tuning speed is higher when the difference value is bigger; and the tuning speed is lower when the difference value is smaller. Hence, the output frequency is highly tuned to the needed output frequency and avoids convergence failure.

### CROSS REFERENCE TO RELATED APPLICATIONS

This application claims the priority benefit of Taiwan application serial no. 91121059, filed on Sep. 13, 2002.

### BACKGROUND OF INVENTION

1. Field of Invention

The present invention relates to a phase lock loop circuit and an operation method thereof. More particularly, the present invention relates to a phase lock loop circuit and an operation method thereof, in which a voltage control oscillator (VCO) of the phase lock loop circuit is controlled by a counter.

2. Description of Related Art

Today, a phase lock loop (“PLL”) technique is widely used in every aspect of electronics and automatic control, such as a conventional radio transceiver or a sophisticated missile.

A conventional PLL circuit 100, depicted in FIG. 1A, includes a phase comparing circuit 14, a low pass filter (LPF) 18, and a voltage control oscillator (“VCO”) 20. The phase comparing circuit 14 is used for phase comparison, which compares the phases of an input signal 10 received by the PLL circuit 100 and an output signal from the VCO 20, and then generates an error signal 16 based on the phase difference between the input signal 10 and the output signal 20. The low pass filter 18 is to used to filter out a high frequency component of the error signal 16 and a high frequency noise occurred in the loop to assure the performance of the PLL circuit 100, thus increases system stability.

After the error signal 16 passes through the LPF 18, a control voltage 22 is obtained, which is used to control the VCO 20 to make the frequency of the output signal 12 closer to that of the input signal 10 until the frequency deviation vanishes and lock is achieved.

The PLL circuit 100 circuit is a control system of a phase error. It is used to compare the phase difference of the input signal 10 and the output signal 12 generated by voltage control oscillation, then generates the error signal 16 and the control voltage 22 to adjust the VCO 20 to achieve the same frequency as the input signal 10. When the PLL circuit 100 starts to work, if the frequency of the input signal 10 received by the PLL circuit 100 and the output signal 12 of the VCO 20 are different, then a certain frequency difference exists and the phase deviation between them varies. Continuously, under this circumstance, the frequency of the output signal of the VCO 20 also varies. This condition is called an unlock status of the PLL circuit 100. If the frequency of the output signal of the VCO 20 is equal to that the input signal 10, under the condition of stability satisfaction, the output signal 12 stabilizes to the frequency of the input signal 10. The frequency difference between the input signal 10 and the output signal 12 is substantial zero. Phase does not vary with time and the error voltage is a fixed value. This condition is called a lock status of the PLL circuit 100. On the contrary, the PLL circuit 100 remains unlocked before the cancellation of frequency deviation between the output signal 12 and the input signal 10.

The input signal 10 is a fixed value, for example, a crystal oscillator provides a 14 MHz frequency. In practice, a different frequency is applied to input signal 10 according to a different situation. Therefore, a frequency divider 24 and another frequency divider 26 are added to formulate a PLL circuit 200, as shown in FIG. 1B. The frequency divider 24 is located in front of the phase comparing circuit 14 to make the input signal 10 being divided by N. The frequency divider 26 is positioned between the VCO 20 and the phase comparing circuit 14 to make the output signal 12 being divided by M. The frequency-divided input signal 10a and the frequency-divided output signal 12a are compared within the phase comparing circuit 14. Then an error signal 16a is generated in accordance with the phase difference between two respective signals. The error signal 16a is then transmitted to the LPF 18 and then a control voltage 22 is generated.

The VCO 20 is controlled by the control voltage 22 to make the frequency of output signal 12 of VCO 20 being closer to that of the input signal 10 until the frequency deviation there-between disappears and enters a lock status. The frequency of the output signal 12 and the input signal 10 may not be equal because they have a M/N ratio relationship. Therefore, the frequency dividers 24 and 26 added in the PLL circuit 200 can remove a requirement that the respective frequencies between the output signal 12 and the input signal 10 must be equal. The ratio relationship of the frequency dividers 24 and 26 can be adjusted in accordance with design requirements for different frequency needs.

There are some drawbacks in the conventional PLL circuit, for example, the problem of wrong frequency-divided, which arises from the faulty design of the low pass filter. The low pass filter does not filter out some high-frequency component. Some frequency components, which have an integer ratio relationship with the output signals, cause the phase comparing circuit failing to discriminate the frequency difference. The above result locks the frequency of the output signal at a higher level.

Referring to FIG. 1C and FIG. 1D, if a start point of a cycle of a frequency-divided input signal received by the PLL circuit and an start point or an end point of one cycle of a frequency-divided output signal generated by the VCO happen to appear simultaneously, and an end point of the cycle of the frequency-divided input signal and the start point or end point of another cycle of the frequency-divided output signal happen to appear simultaneously (as reference numbers 30 or 32 of FIG. 1C and FIG. 1D), the phase comparing circuit cannot make a decision and the aforementioned causes a false frequency multiple phenomenon. Or the voltage control oscillator (VCO) merely provides a single speed to adjust the output signal to tune the frequency to meet output expectation. However, under certain circumstances, e.g. a large adjustable scale causes the output frequency to be lower or higher than the ideal frequency, the output frequency becomes higher (or lower) after adjustment, then slower (or higher) again after another adjustment, and so on. Or the output of the error signal 16 of the phase comparing circuit 14 is slower and leads to an adjustable gap. All the above conditions cause the output adjustment frequency to oscillate up and down around the expected output frequency and fails to converge. Moreover, in high magnitude frequency synthesis, the phase comparing circuit of the conventional PLL circuit needs a longer time for comparing and generating an error signal, so the lock time is longer and it is uneasy to converge. Therefore, problems about frequency shift and failing to lock effectively arise.

In order to solve the above problems, the present invention provides a method to overcome the drawbacks of the conventional PLL circuit and improve performance and reliability.

### SUMMARY OF INVENTION

Based on above background, there are problems about wrong frequency multiple, failure to converge and frequency shift for high magnitude synthetic frequency for the conventional PLL circuit. Therefore, the purpose of the invention is to provide a phase lock loop circuit and an operation method thereof, in which a voltage control oscillator (VCO) of the phase lock loop circuit is controlled by a counter. The speed of the VCO is controlled by utilizing the cycle time difference between a frequency of an input signal received by the PLL circuit and a frequency of an output signal from the VCO. Counting the time difference with a counter, to adjust the output frequency of the VCO based on the time difference to avoid wrong frequency multiple. Thus, error probability is decreased and the reliability of the PLL circuit is increased.

Another purpose of the invention is to provide a method of controlling VCO speed, utilizing the cycle time difference between a frequency of an input signal received by the PLL circuit and a frequency of an output signal from the VCO. Counting the time difference with a counter, to adjust the adjustment speed of the VCO based on the time difference. As a result, the PLL circuit can converge effectively and without divergence.

Another purpose of the invention is to provide a method of controlling VCO speed, utilizing the cycle time difference between a frequency of an input signal received by the PLL circuit and a frequency of an output signal from the VCO. Counting the time difference with a counter, to adjust the adjustment speed of the VCO based on the time difference. The adjustment speed can be faster or slower depending on real time difference. In general, the method can make the output frequency quickly converge to the appointed frequency to reduce lock time to increase performance of the PLL circuit.

Another purpose of the invention is to provide a method of controlling VCO speed, utilizing the cycle time difference between a frequency of an input signal received by the PLL circuit and a frequency of an output signal from the VCO. Counting the time difference with a counter, to adjust the adjustment speed of the VCO based on the time difference. The computing process can be done in one cycle, so the VCO speed adjustment makes the PLL circuit quickly converge to the preset frequency during synthesize a high magnitude frequency. Therefore, the high magnitude frequency synthesis has no frequency shift problem due to the long phase comparing period. The system stability of PLL circuit is increased.

Another purpose of the invention is to provide a method of controlling VCO speed, which can avoid wrong frequency multiple. As a result, it can eliminate the low pass filter to filter out the high frequency component, as the LPF is likely to generate the wrong frequency due to a wrong frequency multiple problem. So the system can omit LPF to reduce cost and circuit space.

To achieve these and other advantages and in accordance with the purpose of the invention, as embodied and broadly described herein, the invention provides a phase lock loop circuit including a counter and a voltage control oscillator. The counter is used for obtaining a first value and a second value by respectively counting an input signal with a first frequency received by the phase lock loop circuit within one cycle period and counting an output signal with a second frequency within the same cycle period, wherein a third value is obtained by comparing the difference of the first value and the second value. The voltage control oscillator is used for generating the output signal, wherein when the voltage control oscillator obtains the third value from the counter, modifying the frequency of the output signal in response to the third value for the phase lock loop circuit.

In the above-mentioned phase lock loop circuit, the speed of modifying the second frequency of the output signal of the voltage control oscillator varies with the third value. When the third value becomes larger, the speed of modifying the second frequency of the output signal becomes faster, when the third value becomes smaller, the speed of modifying the second frequency of the output signal becomes slower.

In the above-mentioned phase lock loop circuit, in an alternative embodiment, further including a first frequency divider. Before obtaining the first value, the first frequency of the input signal received by the phase lock loop circuit is divided by the first frequency divider with a first number and the first value is obtained in response to the divided first frequency of the input signal.

In the above-mentioned phase lock loop circuit, in an alternative embodiment, further including a second frequency divider. Before obtaining the second value, the second frequency of the output signal from the voltage control oscillator is further divided by the second frequency divider with a second number and the second value is obtained in response to the divided second frequency of the output signal.

In the above-mentioned phase lock loop circuit, in an alternative embodiment, further including a loop filter located between the counter and the voltage control oscillator. Before modifying the second frequency of the output signal in response to the third value, the third value is further filtered by the loop filter to filter out a high frequency noise existed in the phase lock loop circuit.

To achieve these and other advantages and in accordance with the purpose of the invention, as embodied and broadly described herein, the invention provides an operation method of a phase lock loop circuit. In the method, a first value and a second value are obtained by respectively counting an input signal with a first frequency received by the phase lock loop circuit within one cycle period and counting an output signal with a second frequency from a voltage control oscillator within the same cycle period. A third value is obtained by comparing the difference of the first value and the second value and forwarding to the voltage control oscillator. The frequency of the output signal is modified in response to the third value for the phase lock loop circuit.

In the above-mentioned operation method of a phase lock loop circuit, the speed of modifying the second frequency of the output signal of the voltage control oscillator varies with the third value. When the third value becomes larger, the speed of modifying the second frequency of the output signal becomes faster. When the third value becomes smaller, the speed of modifying the second frequency of the output signal becomes slower.

In the above-mentioned operation method of a phase lock loop circuit, before obtaining the first value, the first frequency of the input signal received by the phase lock loop circuit is further divided by a first frequency divider with a first number and the first value is obtained in response to the divided first frequency of the input signal.

In the above-mentioned operation method of a phase lock loop circuit, before obtaining the second value, the second frequency of the output signal from the voltage control oscillator is further divided by a second frequency divider with a second number and the second value is obtained in response to the divided second frequency of the output signal.

Based on the purposes described above, the invention provides a method of controlling the speed of the VCO. Utilizing the adjustment of the speed of the VCO to assure that the output frequency converges to preset frequency to increase system stability. It uses non-unique, nonlinear convergent speed to reduce the lock time and to improve system efficiency. The method is effective for a high magnitude frequency synthesis and converge quickly to the preset frequency. Thus, the invention solves the frequency shift problem of high magnitude frequency synthesis and increases the system stability of the PLL circuit. In addition, the invention can effectively lock the frequency without the LPF. Therefore the invention can eliminate LPF to reduce cost and circuit space.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B show schematic block diagrams of a conventional PLL circuit.

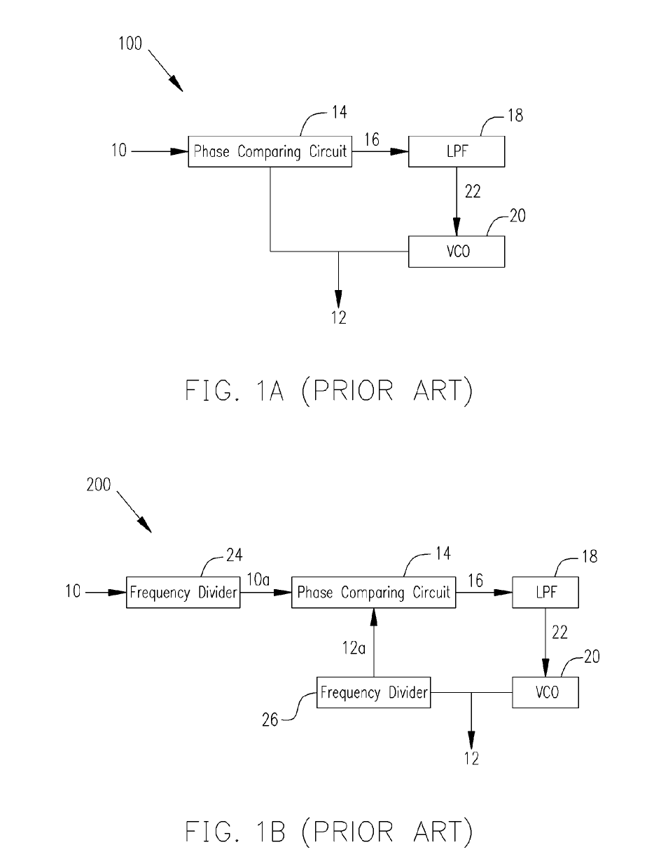

FIG. 1C and FIG. 1D show schematic time charts of wrong frequency dividing of the conventional PLL circuit of FIG. 1A and 1B.

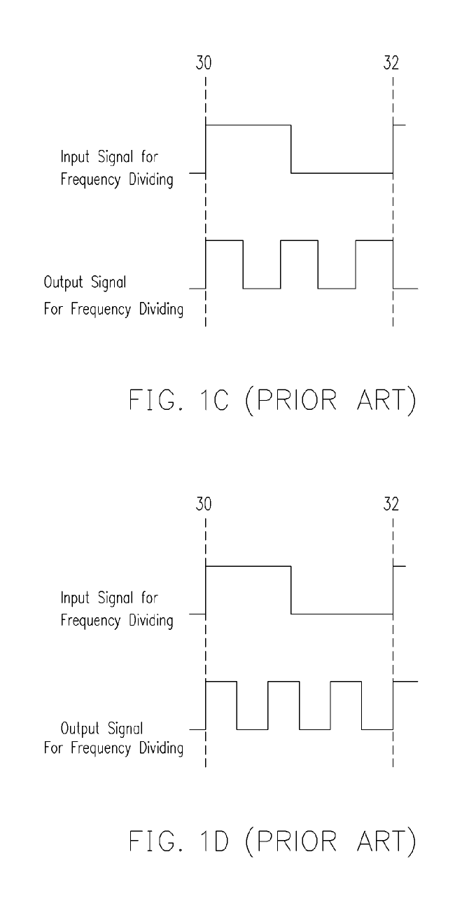

FIG. 2A and FIG. 2B show block diagrams of a phase lock loop synthesizer of a preferred embodiment of the present invention.

FIG. 2C to FIG. 2E show block diagrams of a PLL circuits of another preferred embodiment of the present invention.

FIG. 2F shows time charts of a counting method of the counter used in the phase lock loop synthesizer of FIGS. 2A-2E.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

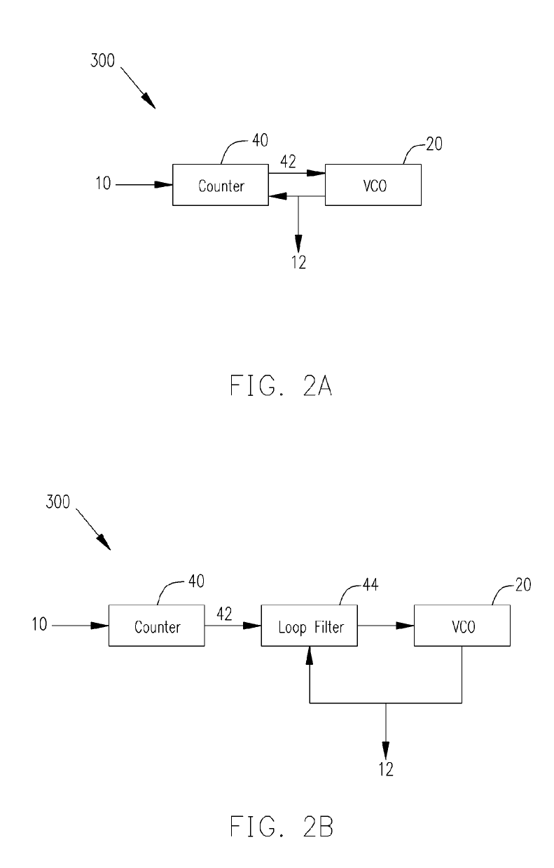

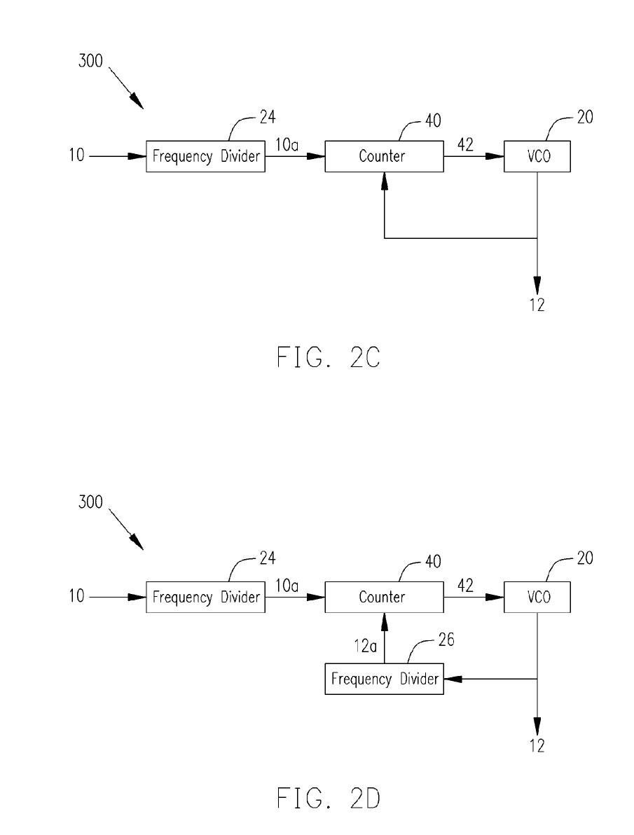

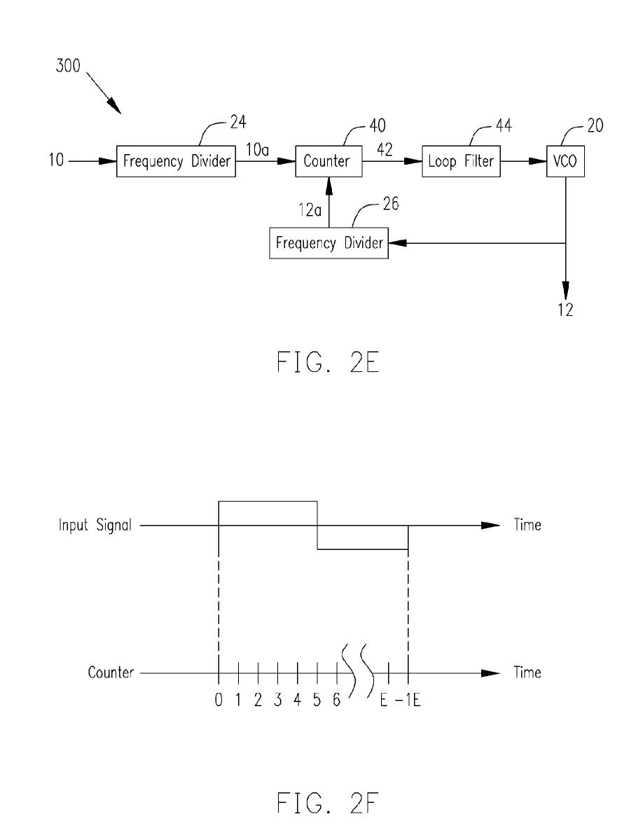

A preferred embodiment of the invention is shown in FIG. 2A. In the embodiment, a phase lock loop (“PLL”) 300 includes two components: a counter 40 and voltage control oscillator (VCO) 20. The counter 40 computes a cycle time of an input signal 10. In one alternative embodiment, the value computed by the counter 40 is shown in FIG. 2F, which is generated as an expectation value E. The counting value by the counter 40 is denoted as “X” within a cycle time of an frequency of an output signal 12 from the VCO 20. The counter 40 outputs an error signal 42 in accordance with the difference between the expectation value E and the counting value X. Thus, when the frequency difference between the input signal 10 and the output signal 12 becomes larger, the error signal 42 also becomes larger, accordingly. On the contrary, when the frequency difference between the input signal 10 and the output signal 12 become smaller, the error signal also becomes smaller accordingly. The value of the error signal 42 is used to control the VCO 20, speeding up or slowing down the speed of the VCO 20. The speed of adjusting the frequency of the output signal 12 is according to frequency deviation between the input signal 10 and the output signal 12. This can avoid the condition that the phase comparing circuit has a single positive or negative output, i.e. only one adjustment speed.

Therefore, in the preferred embodiment as shown in FIG. 2A, the PLL circuit 300 adopts the counter 40 to generate the error signal 42 based on the difference between the counting value X of the output signal 12 and the expectation E. The error signal 42 controls the speed of the VCO 20, not just adjusts a fixed speed. In doing so, when the frequency of the output signal 12 is far from expectation, then it can quickly be modified to the expected frequency. When the frequency of the output signal 12 approaches expectation, it can be finely tuned to the expected frequency to avoid over modification. Hence it can achieve a lock status rapidly and avoid divergence, by which the performance, reliability, and stability of the PLL circuit 300 is significantly improved. In addition, the counter 40 can generate the expectation value E and the counting value X during one cycle of the input signal 10 or the output signal 12, so the generating time of the error signal does not be lengthened and the lock status can be achieved quickly for high magnitude frequency synthesis.

Moreover, the invention can also adapt a loop filter 44 (FIG. 2B) to filter out the high frequency noise of a frequency difference signal, making the output of the VCO 20 smoother to avoid a frequency spurious pulse being generated in the output signal 12 of the VCO 20.

Another preferred embodiment of the invention is shown as FIG. 2C. In the preferred embodiment, the PLL circuit 300 includes three components: a counter 40, a VCO 20 and a frequency divider 24. The frequency divider 24 has a frequency division number N. The frequency of the input signal 10 can be divided by N to generate a frequency-divided signal 10a. The frequency-divided signal 10a is coupled to the counter 40. The counter 40 computes the frequency-divided signal 10a for one cycle and generates an expectation value “E”. A counting value of the counter 40 for one cycle of the output signal 12 is denoted as “X”. Therefore, the counter 40 can output an error signal 42 based on the difference between the expectation value E and the counting value X. Thus, when the frequency difference between the frequency-divided signal 10a and the output signal 12 becomes larger, the error signal 42 also becomes larger, accordingly. On the contrary, when the frequency difference between the frequency-divided signal 10a and the output signal 12 become smaller, the error signal also becomes smaller accordingly. The value of the error signal 42 is used to control the VCO 20, speeding up or slowing down the speed of the VCO 20. Similarly, the frequency divider also can be located between the output of the VCO 20 and the input of the counter 40 in the same circuit, on which the VCO 20 outputs the output signal 12 to the counter 40. The frequency divider 24 divides the frequency of the output signal 12 and then inputs the result to the counter 40. The counter 40 compares the frequency-divided signal 10a and the output signal 12a and then sends the error signal 42 to the VCO 20 after comparison.

In the preferred embodiment, the PLL 300 uses the counter 40 to generate the error signal 42 based on the difference between the counting value X of the output signal 12 and the expectation value E of the frequency-divided signal 10a. In another preferred embodiment of the invention, another frequency divider can be alternatively located between the VCO 20 and the counter 40, as shown in FIG. 2D. The frequency divider 26 receives the output signal 12 and then outputs a frequency-divided signal 12a to the counter 40. Then the counter 40 generates the error signal 42 based on the difference between a count value X generated in accordance with the output signal 12a and an expectation value E in accordance with the frequency-divided signal 10a, as shown in FIG. 2D. The error signal 42 can control the speed of the VCO 20 to generate non-unique, non-linear convergence. The error signal 42 can help the PLL 300 to achieve a lock status rapidly under a high magnitude frequency synthesis and avoid failure of convergence. That can improve the performance, reliability, and stability of PLL circuit 300. Moreover, the frequency divider can maintain the frequency of the input signal 10 and the output signal 12 in a certain magnification N. Thus the frequency range of the output signal 12 can differ from that of the input signal 10. Instead, the magnification N can be adjusted to get the appropriate the output frequency depending on different needs. In addition, the frequency divider 24 (frequency-divided magnification N) and the frequency divider 26 (frequency-divided magnification M) can be added to the circuit simultaneously, on which the counter 40 outputs the error signal 42 to VCO 20 and VCO 20 outputs the signal to counter 40. The counter 40 receives the frequency-divided signal 10a and the frequency-divided signal 12a, making the output frequency become M/N times of the frequency of the input signal 10, by which provides a various magnitude conversion, as shown in FIG. 2D.

In an alternative embodiment, a loop filter 44 is located between the counter 40 and the VCO 20, as shown in FIG. 2E. The loop filter 44 is used to filter out a high frequency noise of a frequency difference signal, to let the output of VCO 20 be more smoother and avoid a frequency spurious pulse being generated in the output signal 12 of the VCO 20.

In an alternative embodiment, the counter 40 of the preferred embodiment of the invention can be combined with the frequency divider, which forms a programmable counter, which generates multiple frequencies according to different needs. A crystal oscillator can be alternatively used to provide the input frequency to the counter 40 to generate the needed output frequency.

To sum up, the invention has disclosed a method of controlling a VCO in a PLL frequency synthesizer. Based on the method, it is assured that output frequency can converge to a preset output frequency quickly, to increase system stability. In addition, applying a non-unique, non-linear convergent speed shortens the lock time and increases system efficiency. The above method can also apply to a high magnitude frequency synthesis and quickly converge to the preset frequency. Therefore, it can solve the frequency shift problem of the high magnitude frequency synthesis to increase system stability of the PLL circuit. Moreover, the method can lock frequency effectively without a low pass filter, hence the low pass filter can be removed to reduce the cost and save the needed space of the circuit.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An operation method of a phase lock loop circuit, comprising:
obtaining a first value and a second value by respectively counting an input signal with a first frequency received by the phase lock loop circuit within one cycle period and counting an output signal with a second frequency from a voltage control oscillator within the same cycle period;
obtaining a third value by comparing the difference of the first value and the second value and forwarding to the voltage control oscillator; and
modifying the second frequency of the output signal in response to the third value for the phase lock loop circuit and forwarding to a counter until the difference of the first value and the second value is substantial zero.

2. The operation method of a phase lock loop circuit as claimed in claim 1, wherein the speed of modifying the second frequency of the output signal of the voltage control oscillator varies with the third value, wherein
when the third value becomes larger, the speed of modifying the second frequency of the output signal becomes faster, when the third value becomes smaller, the speed of modifying the second frequency of the output signal becomes slower.

3. The operation method of a phase lock loop circuit as claimed in claim 1, wherein before obtaining the first value, the first frequency of the input signal received by the phase lock loop circuit is further divided by a first frequency divider with a first number and the first value is obtained in response to the divided first frequency of the input signal.

4. The operation method of a phase lock loop circuit as claimed in claim 3, wherein before obtaining the second value, the second frequency of the output signal from the voltage control oscillator is further divided by a second frequency divider with a second number and the second value is obtained in response to the divided second frequency of the output signal.

5. The operation method of a phase lock loop circuit as claimed in claim 1, wherein before obtaining the second value, the second frequency of the output signal from the voltage control oscillator is further divided by a second frequency divider with a second number and the second value is obtained in response to the divided second frequency of the output signal.

6. The operation method of a phase lock loop circuit as claimed in claim 1, wherein before modifying the second frequency of the output signal in response to the third value, the third value is further filtered by a loop filter to filter out a high frequency noise existed in the phase lock loop circuit.

7. The operation method of a phase lock loop circuit as claimed in claim 1, wherein the input signal with the first frequency is generated by a crystal oscillator.

8. The operation method of a phase lock loop circuit as claimed in claim 1, wherein combination of the step of calculating the first frequency of the input signal received by the phase lock loop circuit and the step of dividing the first frequency of the input signal are performed by a programmable counter.

9. A phase lock loop circuit, comprising:
a counter, for obtaining a first value and a second value by respectively counting an input signal with a first frequency received by the phase lock loop circuit within one cycle period and counting an output signal with a second frequency within the same cycle period, wherein a third value is obtained by comparing the difference of the first value and the second value; and
a voltage control oscillator for generating the output signal, wherein when the voltage control oscillator obtains the third value from the counter, modifying the frequency of the output signal in response to the third value for the phase lock loop circuit.

10. The phase lock loop circuit as claimed in claim 9, wherein the speed of modifying the second frequency of the output signal of the voltage control oscillator varies with the third value, wherein when the third value becomes larger, the speed of modifying the second frequency of the output signal becomes faster, when the third value becomes smaller, the speed of modifying the second frequency of the output signal becomes slower.

11. The phase lock loop circuit as claimed in claim 9, further comprising a first frequency divider, wherein before obtaining the first value, the first frequency of the input signal received by the phase lock loop circuit is further divided by the first frequency divider with a first number and the first value is obtained in response to the divided first frequency of the input signal.

12. The phase lock loop circuit as claimed in claim 11, further comprising a second frequency divider, wherein before obtaining the second value, the second frequency of the output signal from the voltage control oscillator is further divided by the second frequency divider with a second number and the second value is obtained in response to the divided second frequency of the output signal.

13. The phase lock loop circuit as claimed in claim 9, further comprising a second frequency divider, wherein before obtaining the second value, the second frequency of the output signal from the voltage control oscillator is further divided by a second frequency divider with a second number and the second value is obtained in response to the divided second frequency of the output signal.

14. The phase lock loop circuit as claimed in claim 9, further comprising a loop filter, located between the counter and the voltage control oscillator, wherein before modifying the second frequency of the output signal in response to the third value, the third value is further filtered by the loop filter to filter out a high frequency noise existed in the phase lock loop circuit.

15. The phase lock loop circuit as claimed in claim 9, wherein the input signal with the first frequency is generated by a crystal oscillator.

16. The phase lock loop circuit as claimed in claim 9, wherein the counter and a first frequency divider are combined together to form a programmable counter for generating various frequencies.
